(19) United States
(12) Patent Application Publication
(10) Pub. No.: US 2015/0325439 A1
(43) Pub. Date: Nov. 12, 2015

(54) GROWING CRYSTALLINE SEMICONDUCTOR OXIDE THIN FILMS ON A SUBSTRATE AT A LOW TEMPERATURE USING MICROWAVE RADIATION

(71) Applicant: BOARD OF REGENTS, THE UNIVERSITY OF TEXAS SYSTEM, Austin, TX (US)

(72) Inventors: Arumugam MANTHIRAM, Austin, TX (US); Baby Reeja JAYAN, Austin, TX (US); Katharine L. HARRISON, Austin, TX (US)

(21) Appl. No.: 14/651,725

(22) PCT Filed: Aug. 14, 2013
(86) PCT No.: PCT/US13/54888

§ 371 Date: Jun. 12, 2015

Related U.S. Application Data
(60) Provisional application No. 61/737,687, filed on Dec. 14, 2012.

(51) Int. Cl. H01L 21/02; C23C 18/14; C23C 18/12

(52) U.S. Cl. CPC H01L 21/02628; H01L 21/02491; H01L 21/02565; C23C 18/1254; C23C 18/14; C23C 18/1216

(57) ABSTRACT

A method for growing crystalline semiconductor oxide thin films. A substrate is coated with a conducting oxide (e.g., indium tin oxide). The coated substrate is immersed in a growth solution, such as a solution of a titanium-based sol-gel precursor combined with tetraethylene glycol. The coated substrate and the growth solution are heated in a microwave reactor via microwave radiation. Film growth of crystalline semiconductor oxide thin films (e.g., titanium dioxide thin films) are then catalyzed by microwave interaction with the conducting oxide on the substrate. Such a process enables crystalline semiconductor oxide thin films to be grown on a flexible or heat-sensitive substrate (e.g., plastic) using a low temperature in a fast and inexpensive manner.

### CROSS REFERENCE TO RELATED APPLICATIONS

This application claims priority to U.S. Provisional Patent Application Ser. No. 61/737,687, “Low Temperature Microwave-Assisted Thin Film Deposition,” filed on Dec. 14, 2012, which is incorporated by reference herein in its entirety.

### GOVERNMENT INTERESTS

The U.S. Government has certain rights in this invention pursuant to the terms of the Department of Energy Grant Nos. DE-SC0005397 and DE-SC0001091.

### TECHNICAL FIELD

The present invention relates generally to thin film fabrication, and more particularly to growing crystalline semiconductor oxide thin films on a substrate at a low temperature using microwave radiation.

### BACKGROUND

Design and synthesis of new materials is the cornerstone of materials science. In particular, thin film fabrication is important in fields as diverse as semiconductor devices, optoelectronics, energy harnessing/storage, and medicine. Currently, high temperatures are required to synthesize thin films of semiconductor oxides, preventing the use of plastic-based, light-weight, and flexible substrates for solar cells, light emitting diodes, sensors, and photodetectors. As a result, low-temperature synthesis techniques to grow thin films of semiconductor oxides, which are also facile and energy efficient, are desired.

### BRIEF SUMMARY

In one embodiment of the present invention, a method for growing crystalline semiconductor oxide thin films comprises coating a substrate with a conducting oxide. The method further comprises immersing the coated substrate in a growth solution. Furthermore, the method comprises heating the coated substrate and the growth solution in a microwave reactor via microwave radiation. In addition, the method comprises catalyzing film growth of crystalline semiconductor oxide thin films by microwave interaction with the conducting oxide on the substrate.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE SEVERAL VIEWS OF THE DRAWINGS

A better understanding of the present invention can be obtained when the following detailed description is considered in conjunction with the following drawings, in which:

FIG. 1 is a flowchart of a method for growing crystalline semiconductor oxide thin films at a low temperature using microwave radiation in accordance with an embodiment of the present invention

FIG. 2 depicts a schematic of the microwave reaction scheme in accordance with an embodiment of the present invention;

FIG. 3A illustrates a summary of film growth optimization conditions in accordance with an embodiment of the present invention;

FIG. 3B illustrates that the Grazing Incidence X-Ray Diffraction (GIXRD) pattern for the optimized film grown on ITO-coated glass shows peaks for the ITO layer as well as strong anatase phase peaks, most notably the (101) peak at 25° in accordance with an embodiment of the present invention;

FIG. 3C illustrates the microwave-grown TiO₂ film on ITO-coated glass in accordance with an embodiment of the present invention;

FIG. 3D illustrates the microwave-grown TiO₂ film on aluminum-coated glass in accordance with an embodiment of the present invention;

FIG. 3E illustrates the microwave-grown TiO₂ film on ITO-coated polyethylene terephthalate (PET) in accordance with an embodiment of the present invention;

FIG. 3F illustrates the Raman spectroscopy for films grown on ITO-coated glass and ITO-coated PET in accordance with an embodiment of the present invention;

FIG. 4A is a Transmission Electron Microscopy (TEM) image that indicates 15-20 nm crystallites for a TiO₂ film grown on ITO-coated glass at 150° C. for a 60 minute reaction time inside a microwave reactor with a 10 W/m power ramp rate in accordance with an embodiment of the present invention;

FIG. 4B is a magnified Scanning Electron Microscope (SEM) image of the TiO₂ film grown on ITO-coated glass at 150° C. for a 60 minute reaction time inside a microwave reactor with a 10 W/m power ramp rate in accordance with an embodiment of the present invention;

FIG. 4C is a large area SEM image of the TiO₂ film grown on ITO-coated glass at 150° C. for a 60 minute reaction time inside a microwave reactor with a 10 W/m power ramp rate in accordance with an embodiment of the present invention;

FIG. 4D is an Atomic Force Microscopy (AFM) image showing 100-200 nm self-sintered TiO₂ grains for a TiO₂ film grown on ITO-coated glass at 150° C. for a 60 minute reaction time inside a microwave reactor with a 10 W/m power ramp rate in accordance with an embodiment of the present invention;

FIG. 4E is a conductive AFM topography of the TiO₂ film grown on ITO-coated glass at 150° C. for a 60 minute reaction time inside a microwave reactor with a 10 W/m power ramp rate in accordance with an embodiment of the present invention; and

FIG. 4F is a conductive AFM current map of the TiO₂ film grown on ITO-coated glass at 150° C. for a 60 minute reaction time inside a microwave reactor with a 10 W/m power ramp rate in accordance with an embodiment of the present invention.

### DETAILED DESCRIPTION

As stated in the Background section, design and synthesis of new materials is the cornerstone of materials science. In particular, thin film fabrication is important in fields as diverse as semiconductor devices, optoelectronics, energy harnessing/storage, and medicine. Currently, high temperatures are required to synthesize thin films of semiconductor oxides, preventing the use of plastic-based, light-weight, and flexible substrates for solar cells, light emitting diodes, sensors, and photodetectors. As a result, low-temperature synthesis techniques to grow thin films of semiconductor oxides, which are also facile and energy efficient, are desired.

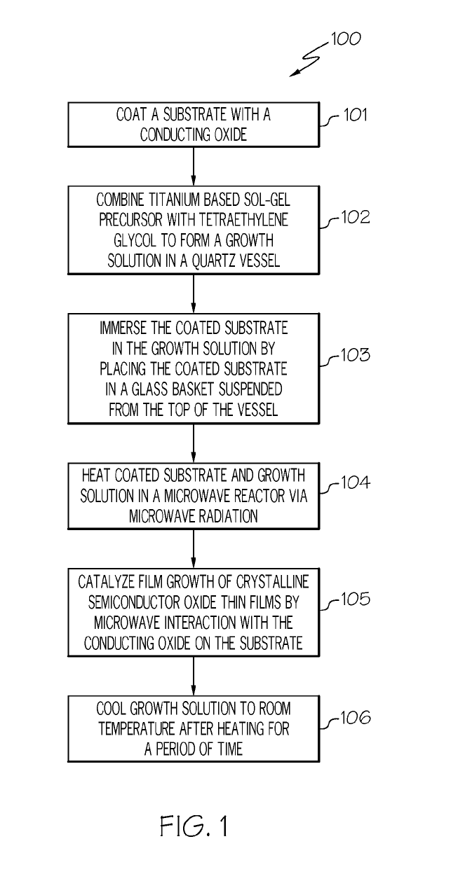

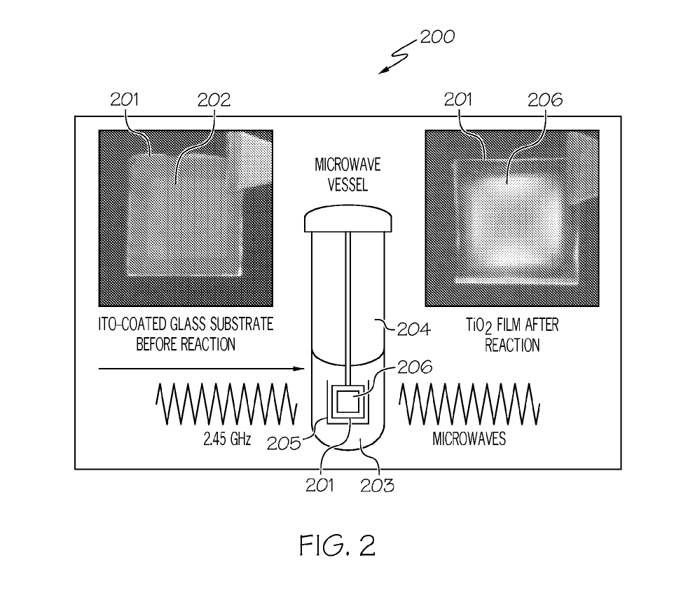

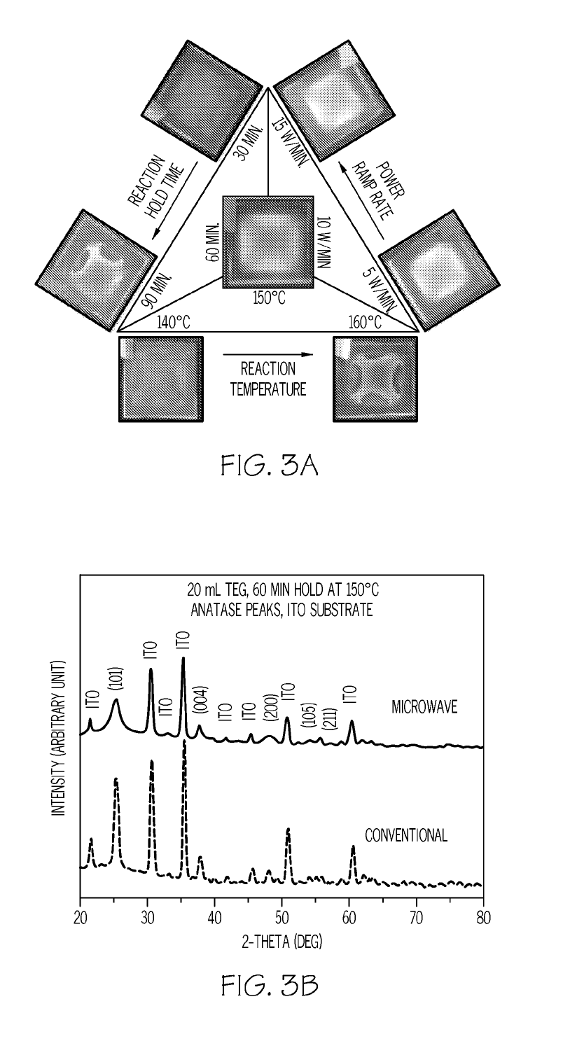

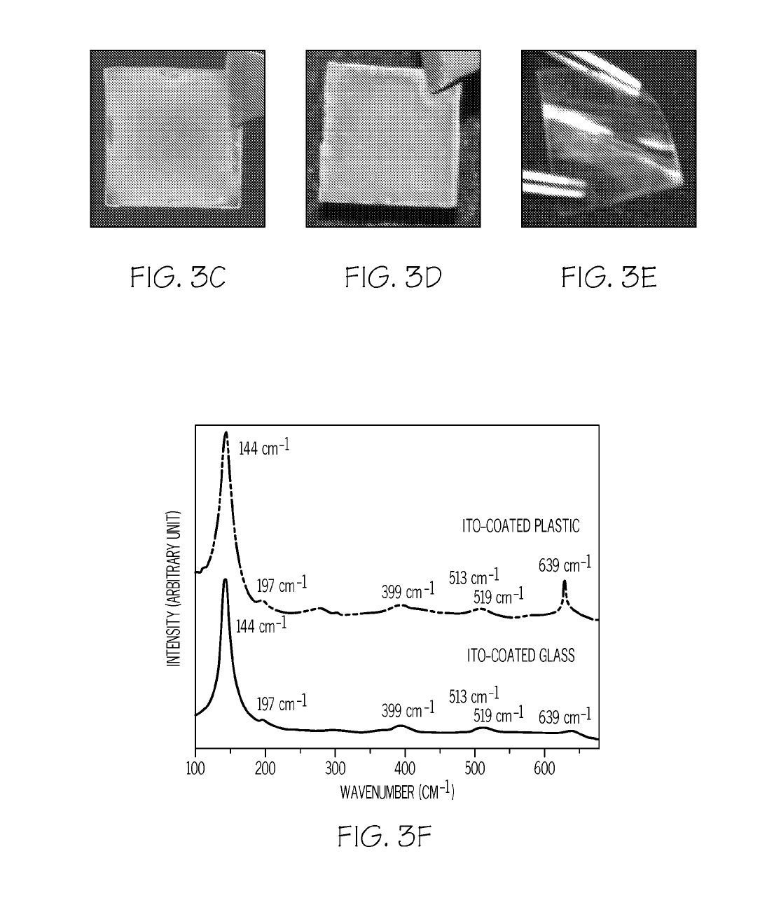

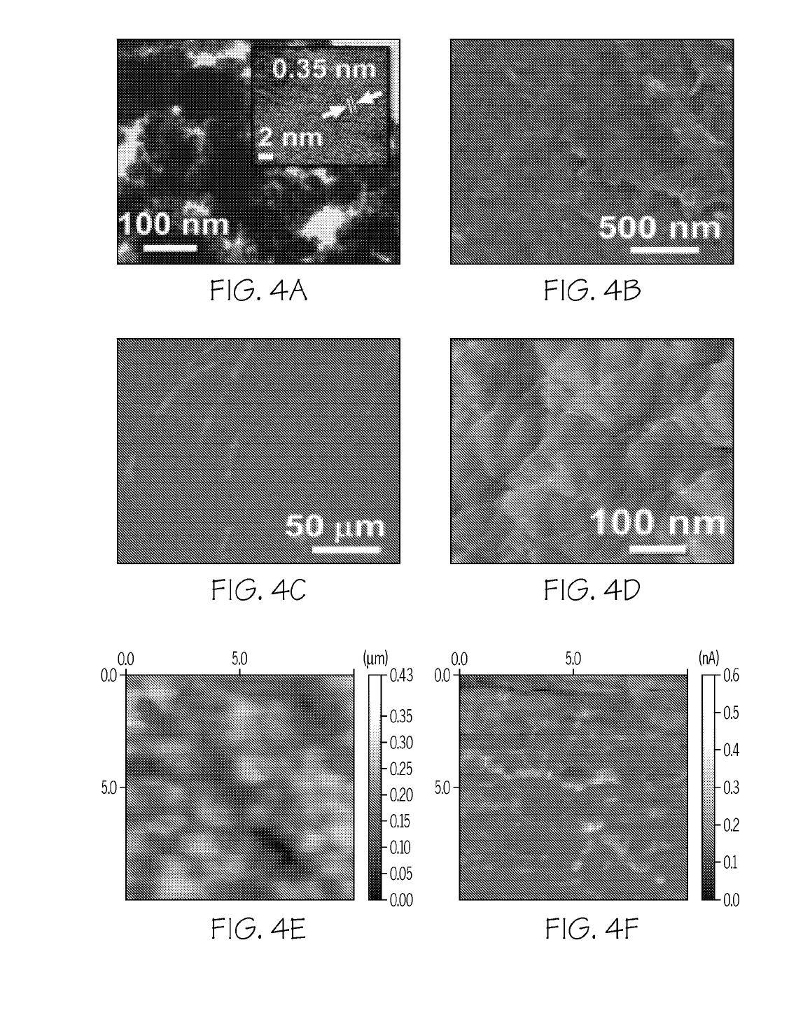

The principles of the present invention provide such a low-temperature technique for growing crystalline semiconductor oxide thin films on a substrate at a low temperature using microwave radiation as discussed below in connection with FIGS. 1-2, 3A-3F and 4A-4F. FIG. 1 is a flowchart of a method for growing crystalline semiconductor oxide thin films at a low temperature using microwave radiation. FIG. 2 depicts a schematic of the microwave reaction scheme. FIG. 3A illustrates a summary of film growth optimization conditions. FIG. 3B illustrates that the Grazing Incidence X-Ray Diffraction (GIXRD) pattern for the optimized film grown on ITO-coated glass shows peaks for the ITO layer as well as strong anatase phase peaks, most notably the (101) peak at 25° . FIG. 3C illustrates the microwave-grown TiO₂ film on ITO-coated glass. FIG. 3D illustrates the microwave-grown TiO₂ film on aluminum-coated glass. FIG. 3E illustrates the microwave-grown TiO₂ film on ITO-coated polyethylene terephthalate (PET). FIG. 3F illustrates the Raman spectroscopy for films grown on ITO-coated glass and ITO-coated PET. FIG. 4A is a Transmission Electron Microscopy (TEM) image that indicates 15-20 nm crystallites for a TiO₂ film grown on ITO-coated glass at 150° C. for a 60 minute reaction time inside a microwave reactor with a 10 W/m power ramp rate. FIG. 4B is a magnified Scanning Electron Microscope (SEM) image of the TiO₂ film grown on ITO-coated glass at 150° C. for a 60 minute reaction time inside a microwave reactor with a 10 W/m power ramp rate. FIG. 4C is a large area SEM image of the TiO₂ film grown on ITO-coated glass at 150° C. for a 60 minute reaction time inside a microwave reactor with a 10 W/m power ramp rate. FIG. 4D is an Atomic Force Microscopy (AFM) image showing 100-200 nm self-sintered TiO₂ grains for a TiO₂ film grown on ITO-coated glass at 150° C. for a 60 minute reaction time inside a microwave reactor with a 10 W/m power ramp rate. FIG. 4E is a conductive AFM topography of the TiO₂ film grown on ITO-coated glass at 150° C. for a 60 minute reaction time inside a microwave reactor with a 10 W/m power ramp rate. FIG. 4F is a conductive AFM current map of the TiO₂ film grown on ITO-coated glass at 150° C. for a 60 minute reaction time inside a microwave reactor with a 10 W/m power ramp rate.

Prior to the discussion of the Figures, a discussion of microwave-assisted synthesis is deemed appropriate. Microwave-assisted synthesis is appealing because it can dramatically reduce reaction time, improve product yield, and enhance material properties when compared to conventional synthesis routes. While conventional heating is limited by thermal conduction from the vessel walls, microwave fields can quickly and uniformly heat a solution by directly coupling to molecules within the solution through polarization or conduction. Polarization is the process of dipoles formed from bound charges and polar molecules aligning with an oscillating electric field. Conduction is the process of free charge carriers and ions moving in response to an electric field. Collisions resulting from dipole rotation during polarization and charge motion during conduction impart energy to the atoms and molecules in the solution in the form of heat; these two types of heating are known as dielectric and ohmic heating, respectively. Thus, microwave heating can be described using a complex permittivity \tilde{ε} of the form

$$\overline{ɛ} = - {ɛ}^{′} j ( - {ɛ}^{″} \frac{σ}{ω} )$$

where ω is the angular frequency of the microwave field and ε′, ε″, and σ are the permittivity, dielectric loss, and electrical conductivity, respectively. While ohmic loss generally dominates when heating conducting solids, the relative contributions of dielectric loss (ε″) and ohmic loss (σ/ω) during solution heating depend on the solvent properties, ion concentration, and frequency.

Microwave-assisted heating phenomena are generally attributed to purely “thermal/kinetic” effects, resulting from uniform or rapid heating. However, “specific” and “non-thermal” microwave effects are debated when microwave reaction products differ from conventional synthesis products. Specific microwave effects are defined as interactions that are thermal in nature but lead to results that cannot be replicated by conventional heating. The specific microwave effect known as “selective heating” refers to preferential energy absorption by materials with high dielectric/ohmic loss. The principles of the present invention exploit a selective heating process to cultivate favorable sites for film nucleation; specifically, a highly microwave energy absorbing conducting layer is placed on an insulating substrate within a solution that absorbs weakly relative to the conducting layer, causing selective heating of the conducting layer and enabling thin film assembly.

Referring now to the Figures in detail, FIG. 1 is a flowchart of a method 100 for growing crystalline semiconductor oxide thin films at a low temperature using microwave radiation in accordance with an embodiment of the present invention. FIG. 1 will be discussed in conjunction with FIG. 2, which depicts a schematic of the microwave reaction scheme in accordance with an embodiment of the present invention.

Referring to FIG. 1, in conjunction with FIG. 2, in step 101, a substrate 201 is coated with a conducting oxide 202, such as indium tin oxide (ITO). A variety of substrates 201 may be used including glass, silicon, metal and flexible or heat sensitive substrates, such as plastic.

In step 102, a titanium-based sol-gel precursor is combined with tetraethylene glycol to form a growth solution 203 in a quartz vessel 204. In one embodiment, 5 ml of the titanium-based sol-gel precursor is combined with 20 ml of tetraethylene glycol in a 80 ml quartz vessel 204.

In step 103, coated substrate 201 is immersed in growth solution 203 by placing coated substrate 201 in a glass basket 205 suspended from the top of vessel 204. In one embodiment, vessel 204 is sealed to allow autogenous pressure to build under solvothermal reaction conditions.

In step 104, coated substrate 201 and solution 203 are heated in microwave reactor 200 via microwave radiation for a period of time. In one embodiment, the microwave radiation is at 2.45 GHz. In one embodiment, coated substrate 201 and solution 203 are heated at approximately 150° C. for approximately 60 minutes. The microwave heating process can be described as follows: the walls of the quartz vessel 204 do not absorb significant microwave energy, allowing solution 203 to be heated directly by dielectric and ohmic mechanisms. Conducting oxide layer 202 (e.g., ITO layer with a conductivity σ˜10⁵ S/m) also absorbs microwave energy (predominantly by ohmic heating) and it does so more efficiently than solution 203, creating a site for crystalline semiconductor oxide thin films 206 (e.g., titanium dioxide (TiO₂)) (discussed below) to nucleate and grow in a single step.

In step 105, film growth of crystalline semiconductor oxide thin films 206 (e.g., titanium dioxide (TiO₂) thin films) is catalyzed by the microwave interaction with the conducting oxide 202 (e.g., ITO) on substrate 201. In the example using ITO as the conducting oxide 202, the ITO layer strongly absorbs microwave energy, causing localized heating that catalyzes growth of anatase TiO₂ thin films while the solution temperature remains at 150° C. In contrast, classical synthesis routes for anatase films comprise of chemical deposition techniques (sol-gel) and vacuum deposition techniques (sputtering, atomic layer deposition), followed by a high-temperature sintering step at >450 ° C. to crystallize the films. Such high temperatures limit the choice of thin film growth substrates as flexible polymeric/plastic substrates typically decompose between 100 and 300° C.

In step 106, solution 203 is then cooled to room temperature after heating substrate 201 and solution 203 in step 104 for a period of time (e.g., 60 minutes).

In some implementations, method 100 may include other and/or additional steps that, for clarity, are not depicted. Further, in some implementations, method 100 may be executed in a different order presented and that the order presented in the discussion of FIG. 1 is illustrative. Additionally, in some implementations, certain steps in method 100 may be executed in a substantially simultaneous manner or may be omitted.

A more detailed description of the results of implementing method 100 using indium tin oxide (ITO) as the coating on various substrates is provided below in connection with FIGS. 3A-3F and 4A-4F, which will be discussed in conjunction with FIGS. 1 and 2.

In one embodiment, the microwave-assisted film growth process of method 100 was run on ITO-coated glass (using ITO as the conducting oxide 202 and using glass as the substrate 201) under a wide range of conditions to optimize uniformity and crystallinity of the TiO₂ films 206. A summary of the key results, shown in FIG. 3A in accordance with an embodiment of the present invention, reveals that the best film growth occurs at the convergence of optimum temperature and reaction time, but the power ramp rate is not a critical variable. Films 206 grown at 150° C. followed by a 60 minute reaction time appear most uniform. Films 206 are thin at low temperatures and short reaction times, but higher temperatures and longer times cause chunks of film to peel off as films 206 grow too thick. At higher reaction temperatures, shorter reaction times can be used to obtain thinner films 206. Film growth was improved through the use of tetraethylene glycol (TEG). Films 206 grown under optimized conditions are strongly adhered likely owing to oxide-oxide bonding between TiO₂ and ITO. Sonication for 10 minutes in various solvents does not damage films 206. Unlike in conventional film growth techniques, the conductivity of the ITO layer 202 does not decrease during the microwave-assisted film growth process.

The crystallinity of the microwave-grown films was studied with Glancing Incidence X-Ray Diffraction (GIXRD) and Raman spectroscopy. Microwave interaction yields crystalline films starting at temperatures as low as 140° C. Sharper anatase peaks appear at 150° C., as shown in FIG. 3B in accordance with an embodiment of the present invention, which compares the GIXRD patterns of the microwave-grown films with those of conventionally-grown films on ITO-coated glass. Both GIXRD patterns show the appearance of a strong anatase (101) peak at 25°, indicating that the microwave-assisted process results in crystalline, anatase TiO₂ films. FIGS. 3C-3E show microwave deposited TiO₂ films on ITO-coated glass, metal (aluminum)-coated glass, and ITO-coated plastic (polyethylene terephthalate (PET)) substrates, demonstrating that the microwave-assisted film growth process of method 100 can be adapted to various substrates in accordance with an embodiment of the present invention.

The morphology of the microwave-grown TiO₂ films 206 was characterized by several techniques spanning a wide range of length scales. Scanning Transmission Electron Microscopy (STEM) image in FIG. 4A reveals that these films 206 are comprised of aggregates of 15-20 nm crystallites in accordance with an embodiment of the present invention. High-resolution Transmission Electron Microscopy (TEM) imaging (FIG. 4A inset) of these crystallites indicate crystalline fringes with a d-spacing of 0.35 nm, corresponding to the (101) plane of anatase TiO₂. Large area Scanning Electron Microscopy (SEM) images (FIGS. 4B and 4C) reveal a smooth morphology in accordance with an embodiment of the present invention, indicating that films 206 are dense and continuous unlike the loosely bound particles which have been shown previously. Further characterization with Atomic Force Microscopy (AFM) confirms the STEM findings that the microwave-grown TiO₂ films 206 are comprised of 100-200 nm self-sintered grains that are aggregates of smaller crystallites (FIG. 4D) in accordance with an embodiment of the present invention. Conductive AFM (C-AFM) imaging was used to simultaneously map the topography of the microwave-grown TiO₂ films 206 along with areas of varying conductivity. The current map (FIG. 4F) tracks the topography map (FIG. 4E) in accordance with an embodiment of the present invention. These images reveal that the microwave-grown TiO₂ films 206 are uniformly insulating, but the central part of film 206 shows some current leakage.

The thicknesses of optimized films 206 are approximately 2000 nm (thinnest in the middle and thicker at the edges). The samples heated at lower temperatures or shorter times are found to be thinner, and the samples heated at higher temperatures and longer times are thicker. Orientation of substrate 201 inside reaction vessel 204 also has a dramatic effect on film growth. GIXRD patterns show significantly stronger anatase peaks for films 206 grown in the vertical orientation. This observation agrees with visual inspection of films 206 and cross-sectional SEM images, indicating that thinner films 206 grow in the horizontal orientation (200 nm) than in the vertical orientation (2000 nm). This variation suggests stronger interaction between the microwave fields and ITO layer 202 when the latter is placed in a vertical orientation.

The results in FIGS. 3B and 4A show that crystalline anatase TiO₂ films 206 can be grown at a significantly lower temperature (150° C.) compared to conventional techniques (450° C.). It is important to observe that the temperature values reported here are the average solution temperatures, which are the only temperatures that can be measured during the microwave reaction. In fact, different parts of ITO layer 202, substrate 201, and solution 203 can be at different temperatures during the reaction because of their different rates of microwave energy absorption. Specifically, it should be expected that parts of ITO layer 202, which selectively absorbs microwaves, and parts of glass substrate 201 and solution 203 that are in thermal contact with ITO layer 202 are (temporarily) at higher temperatures than the average solution temperature. If the temperatures locally become much higher than the average solution temperature (and remain so for long durations), film growth would be hindered on temperature sensitive substrates. However, it can be deduced that the temperature of substrate 201 during the microwave-assisted film growth process of method 100 cannot be significantly higher than the solution temperature of 150° C., because we are able to grow TiO₂ films 206 on plastic (PET) substrates 201, which have a melting temperature of 250° C., without melting or deforming them (FIG. 3E). The formation of anatase phase cannot be confirmed by GIXRD for TiO₂ films 206 grown on plastic substrates, as PET presents a peak that overlaps with the strongest anatase (101) peak at 25°. Accordingly, Raman spectroscopy analysis was used to compare TiO₂ films 206 grown on ITO-coated plastic substrates (using ITO as the conducting oxide 202 and using plastic as the substrate 201) to the films 206 grown on ITO-coated glass (using ITO as the conducting oxide 202 and using glass as the substrate 201). As indicated in FIG. 3F, Raman analysis of both films show six Raman active modes attributed to anatase TiO₂ 206. The peaks seen at 280 and 630 cm⁻¹ in FIG. 3F can be attributed to the PET substrate 201. Absence of additional peaks suggests that there are no significant impurities leftover from the microwave reaction at 150° C. Thus, Raman analysis confirms that crystalline anatase films 206 grow on the plastic substrate 201, establishing clearly that the microwave-assisted process can be used to grow crystalline films 206 on plastic or temperature sensitive substrates 201.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for growing crystalline semiconductor oxide thin films, the method comprising:
coating a substrate with a conducting oxide;
immersing said coated substrate in a growth solution;
heating said coated substrate and said growth solution in a microwave reactor via microwave radiation; and
catalyzing film growth of crystalline semiconductor oxide thin films by microwave interaction with said conducting oxide on said substrate.

2. The method as recited in claim 1 further comprising:
combining a titanium based sol-gel precursor with tetraethylene glycol to form said growth solution.

3. The method as recited in claim 2 further comprising:
combining said titanium based sol-gel precursor with said tetraethylene glycol in a quartz vessel.

4. The method as recited in claim 3 further comprising:
placing said coated substrate in a glass basket which is suspended from a top of said vessel.

5. The method as recited in claim 2 further comprising:
combining 5 ml of said titanium based sol-gel precursor with 20 ml of said tetraethylene glycol in a 80 ml quartz vessel.

6. The method as recited in claim 1 further comprising:
heating said coated substrate and said growth solution in said microwave reactor at approximately 150° C. for approximately 60 minutes.

7. The method as recited in claim 6 further comprising:
cooling said growth solution to room temperature after said heating for approximately 60 minutes.

8. The method as recited in claim 1, wherein said conducting oxide comprises indium tin oxide.

9. The method as recited in claim 8, wherein said indium tin oxide absorbs microwave energy causing localized heating that catalyzes growth of anatase titanium dioxide thin films.

10. The method as recited in claim 1, wherein said microwave reactor operates at 2.45 GHz.

11. The method as recited in claim 1, wherein said substrate comprises glass.

12. The method as recited in claim 1, wherein said substrate comprises silicon.

13. The method as recited in claim 1, wherein said substrate comprises metal.

14. The method as recited in claim 1, wherein said substrate comprises plastic.
